(19) United States
(12) Patent Application Publication
(10) Pub. No.: US 2006/0202751 A1
(43) Pub. Date: Sep. 14, 2006

(54) Controllable amplifier and method for amplifying a signal

(76) Inventors: Carl Stephelbauer, Ennsdorf (AT); Gerhard Habring, Linz (AT); Manfred Haberl, Linz (AT)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 11/357,478

(22) Filed: Feb. 17, 2006

(30) Foreign Application Priority Data
Feb. 23, 2005 (DE) DE 102005008274.2

(51) Int. Cl. H03F 1/14

(52) U.S. Cl. 330/51

(57) ABSTRACT

A controllable amplifier and a method for amplifying a signal dependent on an analog control signal (CTRL) are disclosed. A first and a second amplifier transistor are each arranged with an assigned cascode transistor in respective current paths. The amplification value of the amplifier transistors in the different current paths is preset by means of a respective control signal by activation of the assigned cascode transistor dependent on a desired signal for the overall amplification (CTRL). The controllable amplifier has application to high-frequency transmission arrangements for signal amplification.

### REFERENCE TO RELATED APPLICATIONS

This application claims the benefit of the priority date of German application DE 10 2005 008 274.2, filed on Feb. 23, 2005, the contents of which are herein incorporated by reference in their entirety.

### FIELD OF THE INVENTION

One or more aspects and/or embodiments of the present invention relate to a controllable amplifier, its use, and a method for amplifying a signal dependent on an analog control signal.

### BACKGROUND OF THE INVENTION

It will be appreciated that, for communications systems according to the mobile telephony standard UMTS, Universal Mobile Telecommunications System, for example, a high-frequency output power must be variably adjustable over a large range. The output power and hence the amplification should preferably be adjustable not in discrete steps, but rather dependent on an analog control signal. As a dynamic range, an interval of around 80 dB is generally required. To supply this amplification that is adjustable by analog means over a wide range, so-called Variable Gain Amplifiers, VGA, are normally used. For these VGA, the amplification is adjusted dependent on an analog control signal, such as a control voltage, for example.

Further requirements for such a controllable amplifier, which can be used for amplifying high-frequency signals, are a good carrier suppression, which in particular is not dependent on the selected output power. Furthermore, it is desirable to achieve a low average power consumption for the controllable amplifier. In particular, the average power consumption should be as low as possible over a preset statistical probability of occurrence of the output power. This increases the standby and talk time of mobile radio units, in which high-frequency amplifiers with analog adjustable amplification are preferably usable.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present one or more concepts of the invention in a simplified form as a prelude to the more detailed description that is presented later.

One or more aspects and/or embodiments of the present invention pertain to specifying a controllable amplifier and a method for amplifying a signal dependent on an analog control signal, in which the average power consumption is low, and which variably enables the adjustment of an output power over a large range.

According to one or more aspects and/or embodiments of the present invention a controllable amplifier includes an input for feeding a high-frequency input signal, an input for feeding an analog control signal for amplification and an output. The amplifier also has a first current path, which comprises a first amplifier transistor and a first cascode transistor. The first current path can be switched between a supply potential connection and a reference potential connection. At least one second current path, comprising a second amplifier transistor and a second cascode transistor, is switched parallel to the first current path in the amplifier. The input for feeding the high-frequency input signal is coupled with a control input of the first amplifier transistor and with a control input of the second amplifier transistor. The first and the second current paths are connected in the output of the controllable amplifier. The amplifier also includes a control facility which couples the input for feeding the analog control signal with a control input of the first cascode transistor and with a control input of the second cascode transistor to supply respective control signals for the cascode transistors dependent on the analog control signal.

According to one or more aspects and/or embodiments of the present invention a method for amplifying a signal dependent on an analog control signal includes supplying a first amplifier stage with a first cascode stage and at least one parallel switched second amplifier stage with a second cascode stage. A high-frequency input signal is then fed into the first and the second amplifier stages. The high-frequency input signal is amplified in the first and/or second amplifier stages dependent upon of the analog control signal activating the respective cascode stages. The amplified signal is then supplied to a common output of the first and second amplifier stages.

According to one or more aspects and/or embodiments of the present invention a parallel connection of at least two current paths is provided, each having an amplifier transistor and a cascode transistor assigned to the amplifier transistor. A high-frequency input signal, to be amplified, is fed to each of the amplifier transistors. The output for tapping an amplified signal derived from the high-frequency input signal is formed at a connecting node of the first and second current paths. The adjustment of the overall amplification occurs in that, depending on an analog control signal, respective control signals are supplied through a control facility for the cascode transistors and these are fed to respective control inputs. The analog control signal is used to control the overall amplification and hence the output power of the controllable amplifier.

According to one or more aspects and/or embodiments of the present invention, in contrast to conventional cascode stages, the suggested cascode transistors are switched as a cascode stage in relation to the amplifier transistors, but are not connected to a fixed control potential. Rather, the cascode transistors are additionally used for adjusting the amplification of the respective current path. For this, a respective control signal dependent on the analog control signal is fed to the cascode transistors. The cascode transistors accordingly fulfill a dual function: on the one hand they are used for the supply of a cascode stage, in particular for improved stability, and on the other hand they facilitate adjusting the respective contributions to the overall amplification by the individual amplifier current paths switched in parallel.

It will be appreciated that more than two current paths can also be provided, and that such paths would be developed and switched as in the first two current paths.

The control signals can provide analog activation for the cascode transistors, meaning that in contrast to a PGC (Programmable Gain Control) principle, no switching operations occur. Thus with the suggested principle, spuria caused by non-ideal switching operations are substantially or fully mitigated. The spectrum mask of a mobile radio standard thus cannot be damaged by respective continuous readjustment of the power. There is furthermore no need for complex calibration routines, such as would arise if the amplification adjustment were to be made in discrete steps with an accuracy of 0.1 dB, as required for UMTS.

Since the suggested principle can be implemented especially advantageously in unipolar circuit technologies, such as metal insulator semiconductor circuit technology, the power consumption can be significantly reduced in comparison to bipolar power amplifiers for high-frequency signals.

Addtioanlly, compared to a PGA operation the suggested VGA operation requires less chip surface, as fewer separate stages are necessary. As a result of the likewise reduced parasitic capacitances from the reduced number of separate stages, the power consumption is also lower. As already explained, no noise signals from switching operations can occur. Even for small amplifier increments, complex calibration is not necessary.

For the individual amplifier stages implemented in the current paths, upward and downward adjustment not in parallel and simultaneously analog by corresponding adjustment of the respective control signal at the cascode transistor is especially advantageous. It is rather preferable if the several parallel-switched amplifier stages are activated and deactivated step-wise. For example, a variable amplification can be achieved in a first amplification range with a current path, while the other current paths are deactivated by a corresponding supply of a control signal for the cascode transistor. In another (e.g., larger) amplification range, an amplifier stage in a current path can be always fully activated, (e.g., at its highest selectable amplification), while for a second current path there is a variable gain control by the application of a corresponding control signal at the assigned cascode transistor.

The amplification ranges can be adjacent, but also overlap, depending on the application.

This step-wise activation or deactivation of individual ones of several parallel-switched stages significantly improves the linearity of the overall amplifier.

In one example, there may only be one amplifier stage in a transition range between greatest and smallest adjustable amplification, while the other amplifier stages, thus the other current paths, are fully activated or deactivated. This facilitates a uniform linearity characteristic over the entire amplification range.

The parallel connection, preferably by soft activation, is furthermore suitable for generating a more robust amplification with lower dependency on process-related fluctuations of the transistors.

The controllable amplifier can be developed for symmetrical or non-symmetrical signal processing. Thus the inputs and outputs for the useful signals to be amplified and after amplification, as well as the current paths, can be implemented either in so-called single-ended or in differential circuit technology.

The activation of the cascode transistor with the control signal for adjustment of the amplification desirably provides a resistance or an inductance or another impedance as negative feedback, in particular in a symmetrical circuit architecture.

A further advantage of the activation of the cascode transistors with the control signal is that this circuit node can be connected on alternating current to reference potential, so that existing parasitic capacitances do not have a negative effect.

The amplifier disclosed herein is particularly applicable in transmission configurations as a high-frequency amplifier.

The control signal for the cascode transistors, which is supplied by the control facility depending upon the analog control signal, is preferably a respective control voltage, which is fed to the cascode transistors as gate voltage. The amplification is adjusted by the presetting of a cascode voltage. By lowering the cascode voltage, a full downward adjustment is achieved (e.g., the amplification of the stage is deactivated).

To supply the step-wise activation and deactivation of the several parallel switched stages in the individual current paths, a large number of comparators can be provided, for example, each of which is connected with one input to a tapping node of a voltage divider, and with a further input to the input for the feed of the analog control signal. The outputs of the comparators control the cascode stages.

The individual amplifier stages in the respective current paths can all be of similar magnitude, but the individual current paths can also be scaled to one another to achieve an amplifier characteristic with an exponential characteristic, for example. By way of example, channel width to channel length ratios can be scaled in amplifier and cascode transistors.

### BRIEF DESCRIPTION OF THE DRAWINGS

The invention is explained in more detail below wherein reference is made to the following drawings.

FIG. 1 is a schematic block diagram illustrating a controllable amplifier according to one or more aspects and/or embodiments of the present invention.

FIG. 2 is another schematic block diagram illustrating a controllable amplifier according to one or more aspects and/or embodiments of the present invention.

FIG. 3 is another schematic block diagram illustrating a controllable amplifier according to one or more aspects and/or embodiments of the present invention.

FIG. 4 is another schematic block diagram illustrating a controllable amplifier according to one or more aspects and/or embodiments of the present invention.

FIG. 5 is a graph illustrating a characteristic curve of a controllable amplifier circuit according to one or more aspects and/or embodiments of the present invention wherein exponential reference potentials are used.

FIG. 6 is a graph illustrating the curve of FIG. 5 on a semilogarithmic scale.

### DETAILED DESCRIPTION OF THE INVENTION

One or more aspects or embodiments of the present invention will now be described with reference to the drawing figures, wherein like reference numerals are used to refer to like elements throughout. It should be understood that the drawing figures and following descriptions are merely illustrative and that they should not be taken in a limiting sense. In the following description, for purposes of explanation, numerous specific details are set forth in order to provide a thorough understanding. It will be appreciated that variations of the illustrated systems and methods apart from those illustrated and described herein may exist and that such variations are deemed as falling within the scope of the present invention and the appended claims.

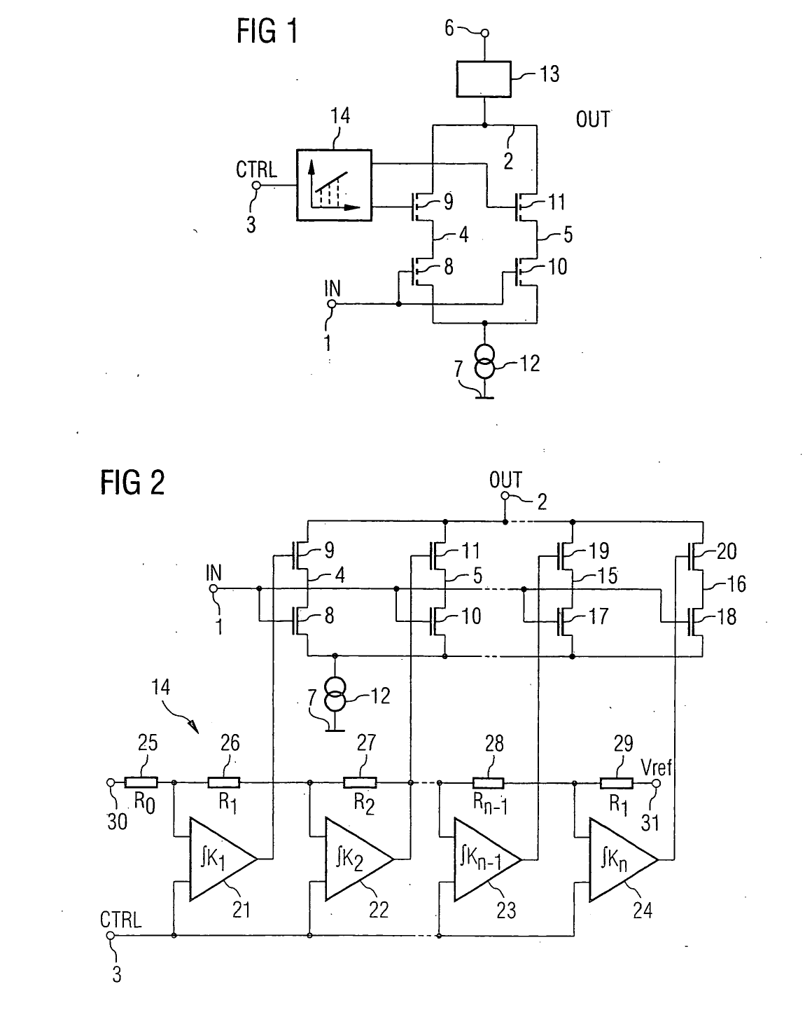

Turning to FIG. 1 a controllable amplifier according to one or more aspects and/or embodiments of the present inveiton is illustrated in so-called single-ended design. The controllable amplifier is accordingly designed for amplification of a signal that can be carried on one line. A high-frequency input signal IN can be fed to an input 1.

An output 2 of the controllable amplifier is used for tapping an output signal OUT. A control input 3 is used for feeding an analog control signal to preset the desired value of the overall amplification between the input 1 and the output 2 of the arrangement. Two current paths 4, 5 are provided, which are switched in parallel between a supply potential connection 6 and a reference potential connection 7. The first current path 4 comprises a first amplifier transistor 8 and a first cascode transistor 9. With the same construction the second current path also comprises a second amplifier transistor 10 and a second cascode transistor 11. In each current path 4, 5 the amplifier transistors 8, 10 and the cascode transistors 9, 11 form a series connection in relation to their controlled sections. These series connections in the current paths 4, 5 are switched parallel to one another between the output 2 and a common power source 12. The supply potential connection 6 is connected via a means for connecting an electrical load 13 to the common output 2. The input 3 for feeding an analog control signal CTRL is coupled with the control inputs of the cascode transistors 9, 11 via a control facility 14, which supplies respective control signals for the cascode transistors dependent on the analog control signal CTRL. The output power that can be tapped at the output 2 is thus proportional to or at least dependent upon the control signal that can be applied at the input 3.

The cascode transistors 9, 11 each form a cascode stage in relation to the amplifier transistors 8, 10 arranged in the same current path. In contrast to conventional cascode stages, however, there is no fixed potential applied to their gate terminals, but rather a control signal that can be fed dependent on the desired analog signal of the overall amplification CTRL. Accordingly the cascode transistors, in addition to the function of the cascode stage, also fulfill the further task of the actual adjustment of the amplification value of the respective amplifier stage, and thus also the overall amplification of the arrangement.

It will be appreciated that more than two current paths can also be provided so that more than two parallel switched amplifier stages are formed. The contribution of each amplifier stage to the overall amplification is controlled by means of the respective cascode transistor, and preset by the control facility, dependent on the analog control signal.

In use as a high-frequency amplifier in a transmitter, the amplifier facilitates carrier suppression independently of the currently selected output power. Because of the implementation in metal-oxide semiconductor, MOS circuit technology and the suggested architecture with the cascode stages activated as suggested, the average power consumption over a preset statistical probability of occurrence of the output power is especially low, and the standby and talk time of a terminal device is thus correspondingly long. Unlike PGAs, since no switching operations occur the power can be continuously readjusted in different transmission methods such as UMTS, without damaging the mask of a frequency spectrum.

FIG. 2 illustrates an amplifier similar to that depicted in FIG. 1, but includes additional current paths. In particular, two further current paths 15, 16 are present in the illustrated example. The current paths 15, 16 likewise comprise respective amplifier transistors 17, 18 and cascode transistors 19, 20 in series connections in relation to their controlled sections. The current paths 4, 5, 15, 16 can be switched parallel to one another.

The control facility 14 comprises respective assigned comparators 21, 22, 23, 24 for the cascode transistor 9, 11, 19, 20, whose output is connected to the gate terminals of the assigned cascode transistor 9, 11, 19, 20. The analog control signal CTRL for presetting the overall amplification is fed to a first input of each of the comparators 21 to 24, which is connected to the control input 3. A second input of each of the comparators 21 to 24 is connected to a tapping node of a resistor divider chain 25, 26, 27, 28, 29. The resistor divider chain 25 to 29 is switched between a reference potential connection 30 and a reference voltage connection 31 for feeding a reference voltage Vref. Different threshold values as switchover thresholds for the individual amplifier stages are thus available to the comparators 21 to 24. The voltage divider compares the analog control voltage with exponential reference potentials, as will be explained in more detail later. Thus starting from 0 and dependent on the analog control signal, the current path 4 of the amplifier is first slowly powered up in analog progression to a first reference value. To generate even greater amplifications, the first current path 4 remains switched to its highest selectable amplification, while the second current path 5 is driven dependent on the analog control voltage by means of the comparator 22 and the assigned cascode stage 11 (while the third and fourth current path 15, 16 remain deactivated). If still greater overall amplification is wanted, the first two current paths 4, 5 remain switched to maximum amplification, while the third current path 15 is controlled and the fourth current path remains deactivated, etc.

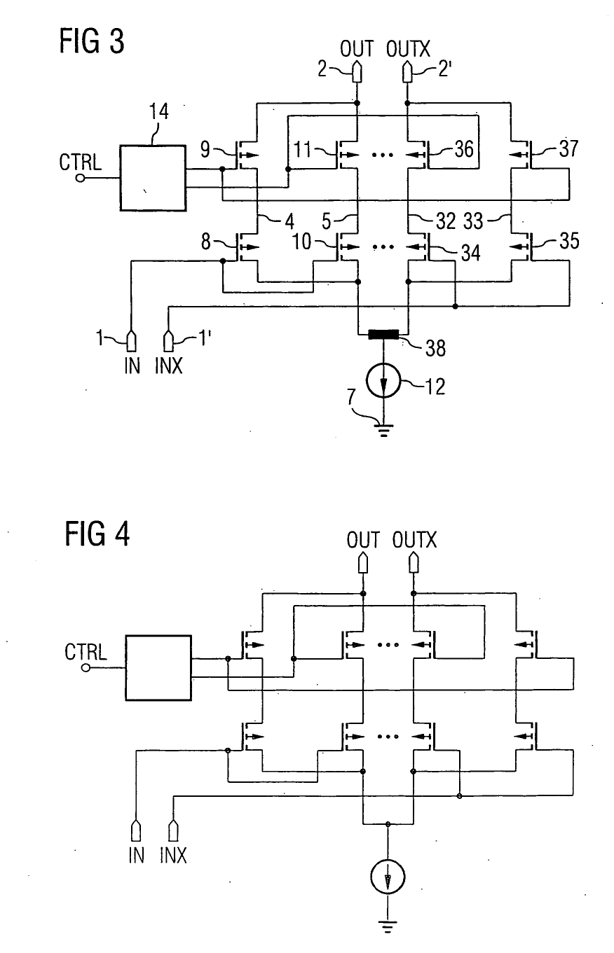

FIG. 3 illustrates an amplifier similar to that depicted in FIG. 1, but includes a differential signal routing that allows the controllable amplifier to have a symmetrical construction. Both the input 1, 1′ and the output 2, 2′ of the controllable amplifier are in this case developed symmetrically for routing differential signals. To each of the current paths 4, 5 a complementary current path 32, 33 is accordingly assigned, which has the same construction, namely each comprising an amplifier transistor 34, 35 and a cascode transistor 36, 37. This therefore results in parallel switched difference amplifiers with cascode stages. The cascode transistors 9, 11, 36, 37 are activated with a respective control signal from the control facility 14. The first current path 4, 33 is thus developed each with two series connections 9, 8; 37, 35, while the second current path comprises the series connections 5, 32 with the amplifier transistors 10, 34 switched to a difference amplifier, with respective cascode stage 11, 36. A common inductance 38 is provided in the base of the difference amplifier for forming a negative feedback, which has a central tapping facility, which is connected via the power source 12 to the reference potential connection 7.

It will be appreciated that more than two differential current paths can also be provided.

The activation of the controllable amplifier according to FIG. 3 can advantageously be effected as described above with respect to FIG. 2 with several switchover thresholds and assigned comparators.

FIG. 4 illustrates an amplifier similar to that depicted in FIG. 3, but includes a DC connection as in FIG. 1, instead of the inductance 38, so that a symmetrical architecture without negative feedback can be implemented.

It will be appreciated that, instead of the enhancement type field-effect transistors of the P channel conductivity type as shown in the above examples, other transistor types can also be used, depending on the application.

FIG. 5 is a graph that illustrates switching points of the comparators 21 to 24 of FIG. 2, which are preset by the resistor divider 25 to 29. In the illustrated example the comparator voltage comparison and the activation of the amplifier stages occurs according to a tangens hyperbolicus, tanh characteristic, which results in an especially smooth transition along the desired output characteristic with moderate slope of the amplifier characteristic, or gain slope.

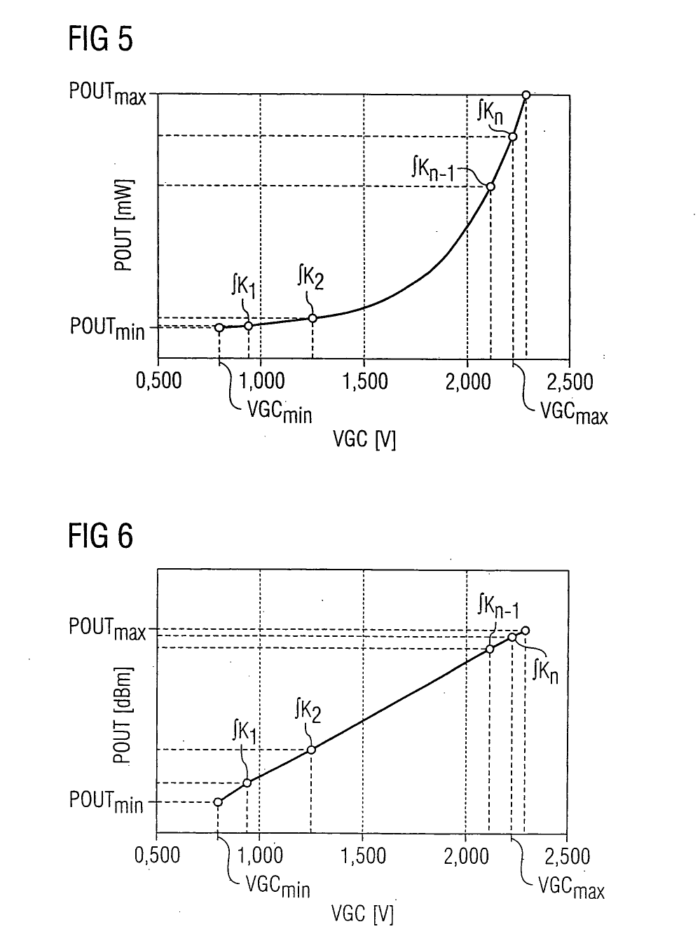

FIG. 6 illustrates the curve of FIG. 5, but in semilogarithmic form. The output characteristic of the amplifier characteristic, which is linear-in-dB, can be seen clearly in this representation.

Although the invention has been illustrated and described with respect to a certain aspect or various aspects, it is obvious that equivalent alterations and modifications will occur to others skilled in the art upon the reading and understanding of this specification and the annexed drawings. In particular regard to the various functions performed by the above described components (e.g., assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.” Also, “exemplary” is merely intended to mean an example, rather than “the best”.

### Reference List

1 Input
1 Output
2 Control signal input
3 Current path
4 Current path
5 Supply potential connection
6 Reference potential connection
7 Amplifier transistor
8 Cascode transistor
9 Amplifier transistor
10 Cascode transistor
11 Power source
12 Means for connecting an electrical load
13 Control facility
14 Current path
15 Current path
16 Amplifier transistor
17 Amplifier transistor
18 Cascode transistor
19 Cascode transistor
20 Comparator
21 Comparator
22 Comparator
23 Comparator
24 Resistor
25 Resistor
26 Resistor
27 Resistor
28 Resistor
29 Reference potential connection
31 Reference voltage connection
32 Current path
33 Current path
34 Amplifier transistor
35 Amplifier transistor
36 Cascode transistor
37 Cascode transistor
38 Inductance

1. A controllable amplifier, comprising:
an input for feeding a high-frequency input signal (IN);
an input for feeding an analog control signal for the amplification (CTRL);
an output (OUT);
a first current path which comprises a first amplifier transistor and a first cascode transistor, and which can be switched between a supply potential connection and a reference potential connection;
at least one second current path comprising a second amplifier transistor and a second cascode transistor, and which is switched parallel to the first current path,
where the input for feeding the high-frequency input signal (IN) is coupled with a control input of the first amplifier transistor and with a control input of the second amplifier transistor,
where the first and the second current paths are connected in the output of the controllable amplifier; and
a control facility which couples the input for feeding the control signal (CTRL) with a control input of the first cascode transistor and with a control input of the second cascode transistor to supply respective control signals for the cascode transistors dependent on the analog control signal (CTRL).

2. The amplifier of claim 1, wherein a means for connecting an electrical load is switched between the supply potential connection on one side and a connection to the first and second cascode transistors on the other side whereon the output of the amplifier is formed.

3. The amplifier of claim 1, wherein the first cascode transistor is switched in the first current path between the first amplifier transistor and the output of the controllable amplifier, and the second cascode transistor is switched in the second current path between the second amplifier transistor and the output of the controllable amplifier.

4. The amplifier of claim 1, wherein the first cascode transistor is switched as a cascode stage in relation to the first amplifier transistor, and the second cascode transistor is switched as a cascode stage in relation to the second amplifier transistor, where a signal dependent on the analog control signal (CTRL) serves as the respective control signal for the cascode stages.

5. The amplifier of claim 1, further comprising:
means of feeding a bias signal arranged in a base of the first and the second current paths.

6. The amplifier of claim 1, wherein the control facility is set up such that one of the two amplifier transistors is operated with the largest or smallest selectable amplification and the other of the two amplifier transistors is operated in a range between the largest and smallest selectable amplification.

7. The amplifier of claim 1, wherein the first and second current paths, the input and the output are configured to route differential signals,
wherein a first series connection in the first current path has the first amplifier transistor and the first cascode transistor,
wherein a second series connection in the first current path has a further first amplifier transistor and a further first cascode transistor,
wherein a first series connection in the second current path has the second amplifier transistor and the second cascode transistor,
wherein a second series connection in the second current path has a further second amplifier transistor and a further second cascode transistor,
wherein a control input of the further first and the further second amplifier transistor is coupled with the input for feeding the high-frequency input signal, and
wherein a control input of the further first and the further second cascode transistor is coupled with the control facility.

8. The amplifier of claim 7, further comprising:
an impedance to form a negative feedback, where the impedance is connected with a first connection to the first and the second amplifier transistors, which is connected with a second connection to the further first and the further second amplifier transistor, and which is coupled in a central tapping facility with the reference potential connection.

9. The amplifier of claim 8, wherein the impedance comprises an ohmic resistor.

10. The amplifier of claim 8, wherein the impedance comprises an inductance.

11. The amplifier of claim 1, wherein the controllable amplifier is integrated in unipolar semiconductor circuit technology.

12. The amplifier of claim 1, wherein the controllable amplifier is used in a high-frequency transmission configuration as a controllable high-frequency amplifier.

13. A method for amplifying a signal dependent on an analog control signal, comprising:
sypplying a first amplifier stage with a cascode stage and at least one parallel switched second amplifier stage with cascode stage;
feeding a high-frequency input signal (IN) to the first and the second amplifier stages;
amplifying the high-frequency input signal (IN) in the first and/or second amplifier stages dependent on the analog control signal (CTRL) activating the respective cascode stages; and
supplying the amplified signal (OUT) to a common output of the first and second amplifier stages.

14. The method of claim 13, wherein activation of the first and the second amplifier stages is dependent on the analog control signal (CTRL) such that one of the two amplifier stages is operated with the largest selectable amplification or the smallest selectable amplification and that the other of the two amplifier stages is operated between the largest and the smallest selectable amplification.

15. The method of claim 13, wherein activation of the first, the second and at least one further amplifier stage is dependent on the analog control signal (CTRL) such that for only one of the amplifier stages an amplification value is selected falling between a smallest and a largest selectable amplification value, while the other amplifier stages are operated either with the smallest or with the largest selectable amplification.

16. The method of claim 13, wherein activation of the first, the second and at least one further amplifier stage is dependent on the analog control signal (CTRL) such that in a first interval of values of a desired overall amplification the second and the at least one further amplifier stage is deactivated and the amplification value of the first amplifier stage is varied, that in a second interval of values of a desired overall amplification the first amplifier stage is operated with its largest selectable amplification, the amplification value of the second amplifier stage is varied and the at least one further amplifier stage is deactivated, and that in a third interval of values of a desired overall amplification the first and the second amplifier stages are operated with their largest selectable amplifications and the amplification value of the at least one further amplifier stage is varied.
